(19) United States
(12) Patent Application Publication
(10) Pub. No.: US 2007/0151707 A1
(43) Pub. Date: Jul. 5, 2007

(54) Method and apparatus for cooling electrical equipment

(75) Inventors: Alan Michael Lyons, Malahide (IE); Alan David O'Loughlin, Dublin (IE); Marc Scott Hodes, New Providence, NJ (US); William Harold Scofield, Batavia, IL (US)

Correspondence Address: WILLIAMS, MORGAN & AMERSON, 10333 RICHMOND, SUITE 1100, HOUSTON, TX, 77042, US

(73) Assignee: LUCENT TECHNOLOGIES, INC.

(21) Appl. No.: 11/323,308

(22) Filed: Dec. 31, 2005

(51) Int. Cl. F28D 15/00; H01L 23/467

(52) U.S. Cl. 165/104.21; 165/121

(57) ABSTRACT

A method is provided for cooling electrical equipment located in distinct regions in a cabinet. A first air flow is provided to a first region in the cabinet. A second air flow is provided to a second region in the cabinet. The temperature of the first and second air flows provided to the first and second regions is substantially equalized to provide similar cooling characteristics within the first and second regions. The equalization is accomplished via a heat exchanger arrangement that may be an active or passive system.

### BACKGROUND OF THE INVENTION

1. Field of the Invention

This invention relates generally to electronic systems, and, more particularly, to cooling components within an electrical system.

2. Description of the Related Art

During the operation of modern electronic equipment, substantial internal heat is generated, which, if not dissipated, can have significant deleterious effects on the equipment. Depending on the equipment and application, inadequate heat dissipation in a system can have a catastrophic impact on system performance, and, in some cases, can result in the entire system shutting down or otherwise failing.

In many applications, the electronic equipment may be housed in a cabinet that is comprised of numerous components and/or boards located on one or more shelves. Typically, cooling air is drawn into the cabinet and then channeled over the various components. The cooling air gradually heats up as it passes over the various components. Thus, those components that are adjacent the entry point of the cooling air may be exposed to cooler air than those components that are more remotely located. For example, the components may be located on three vertically displaced shelf regions with cooling air introduced to either the top or the bottom of the cabinet. The cooling air may be directed upward through the first, second and third shelf regions serially, heating up as it passes through each shelf region, or alternatively, downward through the third, second and first shelf regions serially. Thus, the air passing over the first shelf may be substantially cooler than the air passing over the last shelf, or vice versa. In either case, different regions in the cabinet are exposed to different temperature air. Thus, since any board can generally be located anywhere in the cabinet, each much be designed to operate properly under the harshest thermal condition, i.e., the warmest air.

In the field of telecommunications, the components may be manufactured and supplied by a variety of entities that do not control the location at which the component may be installed within the cabinet. That is, a component or systems manufacturer may not know whether its component or systems will be located in the first shelf region or the third shelf region, or which direction the cooling air will be channeled through the cabinet. Accordingly, manufacturers of these components or systems will typically design for a worst case scenario. That is, the manufacturer will design its component or systems to operate at the worst or highest temperature anticipated to occur within the cabinet. To account for these higher anticipated temperatures, more aggressive and expensive thermal management solution must be implemented in the design of the various components.

### SUMMARY OF THE INVENTION

The present invention is directed to addressing the effects of one or more of the problems set forth above. The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In one aspect of the present invention, a method is provided. The method comprises providing a first air flow to a first region in a cabinet, and providing a second air flow to a second region in a cabinet. The temperature of the first and second air flows provided to the first and second regions are then substantially equalized.

In another aspect of the instant invention, a method is provided. The method comprises providing a first air flow to a first region in a cabinet, and a second air flow to a second region in a cabinet. Heat is transferred from the first air flow to the second air flow.

In still another aspect of the instant invention, an apparatus is provided. The apparatus comprises a cabinet have a first region and a second region and at least one inlet adapted to receive an air flow and pass a first air flow to the first region and a second air flow to the second region. A heat exchanger is positioned to receive the first and second air flows and transfer heat therebetween.

### BRIEF DESCRIPTION OF THE DRAWINGS

The invention may be understood by reference to the following description taken in conjunction with the accompanying drawings, in which like reference numerals identify like elements, and in which:

FIG. 1 conceptually illustrates a front view of at least a portion of one exemplary embodiment of a cooling system in an electrical cabinet, in accordance with the present invention;

FIG. 2 conceptually illustrates a front view of at least a portion of an alternative exemplary embodiment of a cooling system in an electrical cabinet, in accordance with the present invention;

FIG. 3 conceptually illustrates a front view of at least a portion of an alternative exemplary embodiment of a cooling system in an electrical cabinet, in accordance with the present invention;

FIG. 4 conceptually illustrates a front view of at least a portion of an alternative exemplary embodiment of a cooling system in an electrical cabinet, in accordance with the present invention;

FIG. 5 conceptually illustrates a control system that may be implemented in conjunction with the cooling systems of FIGS. 1-4; and

FIG. 6 conceptually illustrates a flow chart representation of a control strategy that may be implemented in conjunction with the control system of FIGS. 5.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF SPECIFIC EMBODIMENTS

Illustrative embodiments of the invention are described below. In the interest of clarity, not all features of an actual implementation are described in this specification. It will of course be appreciated that in the development of any such actual embodiment, numerous implementation-specific decisions may be made to achieve the developers' specific goals, such as compliance with system-related and business-related constraints, which may vary from one implementation to another. Moreover, it will be appreciated that such a development effort might be complex and time-consuming, but may nevertheless be a routine undertaking for those of ordinary skill in the art having the benefit of this disclosure.

Portions of the present invention and corresponding detailed description are presented in terms of software, or algorithms and symbolic representations of operations on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” or “displaying” or the like, refer to the action and processes of a computer system, or similar electronic computing device, that manipulates and transforms data represented as physical, electronic quantities within the computer system's registers and memories into other data similarly represented as physical quantities within the computer system memories or registers or other such information storage, transmission or display devices.

Note also that the software implemented aspects of the invention are typically encoded on some form of program storage medium or implemented over some type of transmission medium. The program storage medium may be magnetic (e.g., a floppy disk or a hard drive) or optical (e.g., a compact disk read only memory, or “CD ROM”), and may be read only or random access. Similarly, the transmission medium may be twisted wire pairs, coaxial cable, optical fiber, or some other suitable transmission medium known to the art. The invention is not limited by these aspects of any given implementation.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

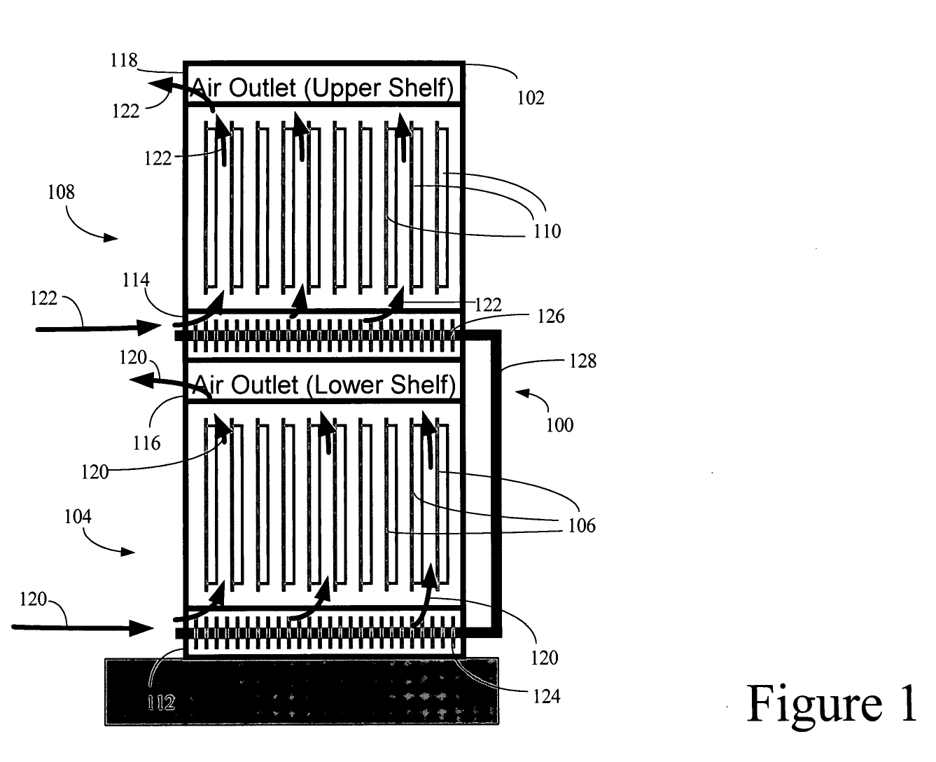

Referring first to FIG. 1, generally, in one embodiment of the instant invention, a heat exchanger or system of heat exchangers 100 is used to try and normalize the temperature of cooling air introduced at different locations in an electrical cabinet 102. The heat exchanger 100 may take any of a variety of forms, including, but not limited to, various types of a heat pips, such as capillary pumped loops, and the like. Loop heat pipes or pumps may be used to circulate fluid inside the heat exchanger. Fins may be used to enhance heat transfer to/from the air streams.

FIG. 1 conceptually illustrates one exemplary embodiment of the electrical cabinet 102. In the illustrated embodiment, the cabinet 102 is shown with a first or lower shelf region 104 in which a plurality of components 106 or printed circuit boards are disposed. The cabinet 102 also includes a second or upper shelf region 108 in which a plurality of components 110 or printed circuit boards are disposed. Those skilled in the art will appreciate that the principles of the instant invention may find application to systems that include a wide variety of numbers of shelf regions, including two or more. Moreover, persons of ordinary skill in the art should appreciate that the present invention is not limited to the illustrated exemplary embodiment.

In the illustrated embodiment, the cabinet 102 has an air inlet 112, 114 and outlet 116, 118 associated with each of the lower and upper shelf regions 104, 108. That is, air flow is provided through the first shelf region 104 by air traveling along a path generally indicated by reference number 120. Cooling air flows into the inlet 112, between the various components 106 and then out of the cabinet through the outlet 116. A set of fans (not shown) or other air handling equipment may be used to urge the cooling air to generally traverse the path 120.

Similarly, air flow is provided through the second shelf region 108 by air traveling along a path generally indicated by reference number 122. Cooling air flows into the inlet 114, between the various components 1110 and then out of the cabinet through the outlet 118. A set of fans (not shown) or other air handling equipment may be used to urge the cooling air to generally traverse the path 122.

Those skilled in the art will appreciate that the temperature of cooling air entering the lower and upper inlets 112, 114 may vary significantly owing to their spaced apart locations. The heat exchanger 100 helps to substantially equalize the temperature of the cooling air that reaches the components 106 in the lower shelf region with the temperature of the cooling air that reaches the components 110 in the upper shelf region. Generally, the thermal coupler 100 operates to transfer heat from the warmer to the cooler inlet 112, 114 and thereby urge the cooling air paths 120, 122 toward equilibrium.

In the illustrated embodiment, the heat exchanger 100 may be comprised of a first and second heat exchangers or radiators 124, 126 and a heat pipe-based or closed-loop pump-based liquid system 128. The heat exchangers 124, 126 may be of a conventional construction having a large surface area composed of a plurality of fins positioned within the inlets 112, 114, respectively so that the cooling air 120, 122 passes thereover either giving up or absorbing heat, depending on the relative temperatures of the cooling air flows 120, 122 and the heat exchangers 124, 126, respectively. That is, assuming that the cooling air flow 122 is relatively warmer than the cooling air flow 120, then the heat exchanger 126 absorbs heat from the air flow 122 and transfers the absorbed heat via the heat pipe 128 to the heat exchanger 124. The heat exchanger 124 then passes this absorbed heat to the air flow 120, raising its temperature and thereby urging the air flows 120, 122 toward a substantially equal temperature. This substantially equalized temperature of the air flows 120, 122 raises the temperature in the lower shelf region 104, but lowers the temperature in the upper shelf region 108. Typically, the designers of the components 106, 110 design each component to operate properly at the highest expected temperature at any location in the cabinet 102. Thus, since use of the instant invention lowers the maximum expected temperature in the cabinet 102, it allows designers of the components 106, 110 to design for a lower expected temperature.

The heat pipe 128 may take on any of a variety of forms, such as a bellows. The bellows arrangement of the heat pipe 128 allows its construction to be flexible and not rigid, which may be particularly useful during the construction of the cabinets or during normal expansion and contraction that may occur due to heating and cooling of the cabinet during its normal operation. Those skilled in the art will appreciate that other coupling methods could also be employed to provide mechanical compliance to this thermal management system in place of the bellows heat pipe.

Those skilled in the art will appreciate that the thermal coupler 100 may not operate to equalize the temperature of the cooling air within the shelf regions 104, 108, but rather, may urge the temperatures toward equilibrium, or at least closer to equilibrium than would occur absent the presence of the thermal coupler 100.

Those skilled in the art will appreciate that the thermal load that the heat pipe 128 can transport is sensitive to heat pipe geometrical orientation. Generally, in the illustrated embodiment, the heat pipe 128 that thermally connects the two shelf regions 104, 108 is orientated perpendicular to the floor. Owing to the fact that heated fluid generally rises, the efficiency of the heat pipe in this geometry is less than desirable when the goal is to transport heat from the upper shelf region 108 to the lower shelf region 104, which would be useful where the temperature of the cooling air in the upper shelf region 108 is substantially higher than the temperature of the cooling air in the lower shelf region 104.

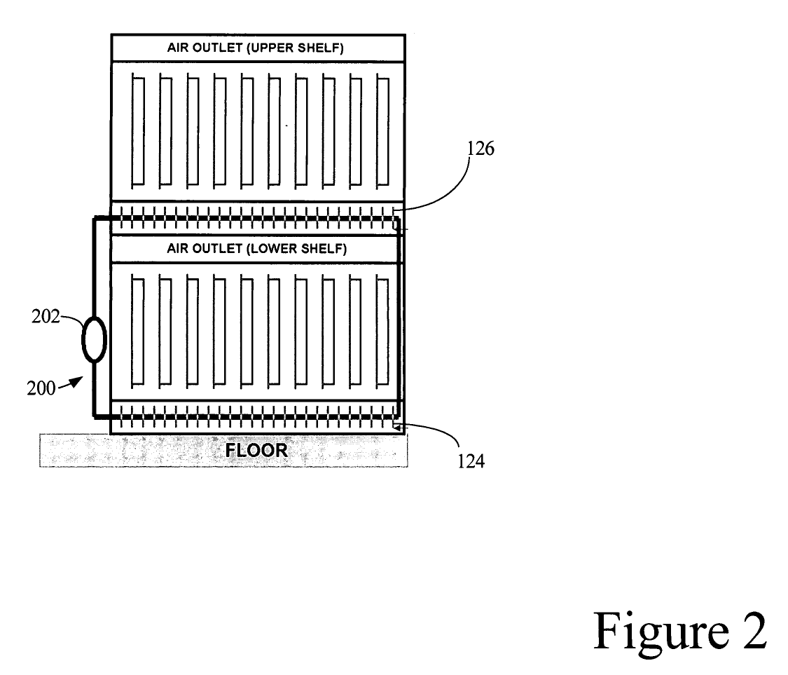

Thus, a hybrid system is also envisioned where the heat exchangers 124, 126 are coupled together with a closed-loop liquid cooling system 200, as shown in FIG. 2. The liquid system of FIG. 2 is capable of efficiently transferring heat between the shelf regions 104, 108 where the goal may be to transmit heat in either an upward or downward direction. There are at least two advantages to this system: 1) the efficiency would be independent of the heat transfer geometry; and 2) the liquid cooling system could be physically isolated from the electronic shelves, thereby increasing the efficiency of this solution. Those skilled in the art will appreciate that active systems, such as pump-based fluid circulation, can accommodate higher heat loads than passive systems, such as heat pipe-based systems.

In one embodiment of the instant invention, the closed-loop liquid cooling system 200 is comprised of the heat exchangers 124, 126, a pump 202 interconnecting the heat exchangers 124, 126, and a return pipe 204. Thus, the pump 202 passes fluid between the heat exchangers 124, 126 to expedite the flow of heat from one inlet 112 to the other 114.

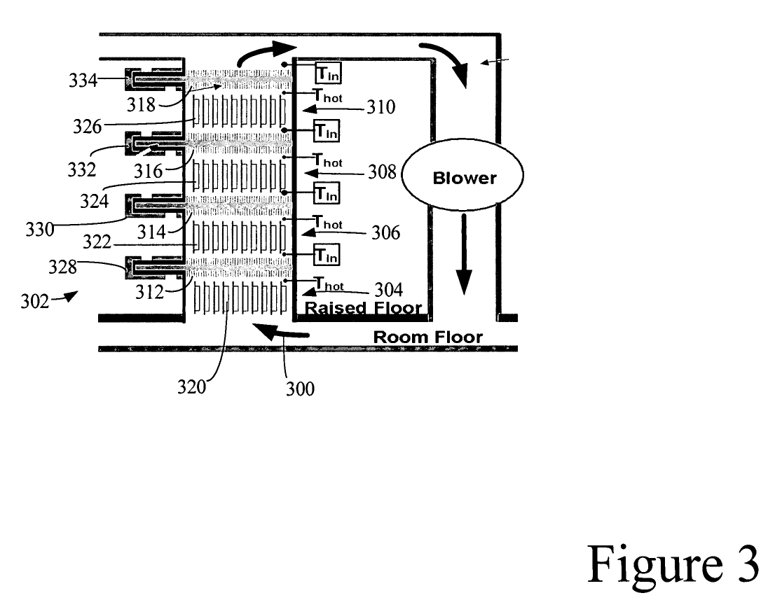

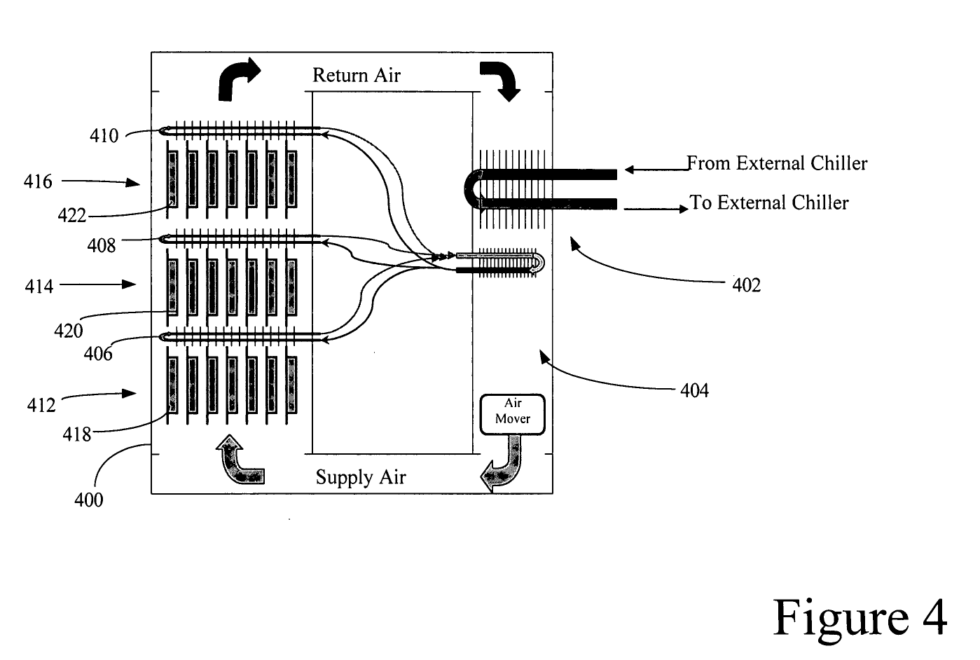

In the embodiments discussed above, the heat exchangers 124, 126 attempt to substantially equalize the inlet temperature of the air streams 120, 122 to the shelf regions 104, 108, but they do not transfer any heat outside of the cabinet. The air from the room or a raised floor is used to provide all of the cooling capacity for both of the shelf regions 104, 108. In alternative embodiments of the instant invention, such as are shown in FIGS. 3 and 4, heat exchangers absorb some or all of the thermal load. Thus, rather than exchange heat between air streams 120, 122 to the different shelf regions 104, 108 (as is done in the embodiments of FIGS. 1 and 2), the heat exchangers remove heat from the air stream flowing through each shelf region to substantially equalize the inlet temperature to each shelf region.

In one embodiment of the instant invention illustrated in FIG. 3, air flow indicated by the reference numeral 300 enters a cabinet 302 having four shelf regions 304, 306, 308, 310. The shelf regions 304, 306, 308, 310 are separated from one another by heat exchangers 312, 314, 316, 318 such that air heated by components 320 within the first shelf region 304 may be cooled down again by the first heat exchanger 312. Similarly, air heated by components 322 within the second shelf region 306 may be cooled down again by the second heat exchanger 314. Likewise, air heated by components 324 within the third shelf region 308 may be cooled down again by the third heat exchanger 316. Finally, air heated by components 326 within the fourth shelf region 310 may be cooled down again by the fourth heat exchanger 318.

If a particular one of the shelf regions 304, 306, 308, 310 in the cabinet 302 dissipates a relatively large amount of heat, its corresponding heat exchanger 312, 314, 316, 318 may lower the temperature of the air entering it by a larger amount than for the other shelf regions, resulting in unequal inlet temperatures. Those skilled in the art will appreciate that when different inlet temperatures are desired for different shelves, then the heat exchangers do not have to be of the same size, but may be sized to provide the desired air temperature at each shelf.

The heat exchangers 312, 314, 316, 318 in this embodiment of the invention are referred to as “radiator trays” because they will resemble a car radiator-type heat exchanger. They may be of very high capacity when absorbing some or all of the heat from the shelf regions 304, 306, 308, 310. Thus there may be one or more finned tubes traversing the cabinet 302 in each heat exchanger 312, 314, 316, 318. The fins on these tubes would absorb the heat from the air flowing through the cabinet 302. The other end of the tubes that transfers the heat to another medium may or may not have fins on it. In the embodiment illustrated in FIG. 3, no fins are present, but the non-finned ends of the heat exchangers 312, 314, 316, 318 are covered by a chilled water jacket 328, 330, 332, 334 to absorb this heat such that fins may not be required. Those skilled in the art will appreciate that if the heat rejection side of the heat exchangers were to transfer heat to cool air, fins might be useful on both ends of the tubes. The chilled water may be supplied from any of a variety of sources, such as a building supply or an air conditioner in the room.

In one embodiment of the instant invention, the tubes in the heat exchangers 312, 314, 316, 318 may be heat pipes, such that a pump may not be needed. When heat pipes do not suffice, due to the limited amount of heat they can transport before failing, a pump may again prove useful, such as in the embodiment illustrated in FIG. 2. Single phase and/or two phase water or refrigerant may be circulated through the tubes in the heat exchangers 312, 314, 316, 318 and transfer heat absorbed from the air flowing through the cabinet 302 may be transferred to the chilled water or cool air in the jackets 328, 330, 332, 334.

Those skilled in the art will appreciate that, when substantially all of the heat from the components 320, 322, 324, 326 is transferred to the heat exchangers 312, 314, 316, 318, it may not be necessary to cool the air in the room through air conditioning before it enters the cabinet 302. Those skilled in the art will also appreciate that while the embodiment of FIG. 3 is illustrated with the air flow 320 entering the bottom of the cabinet 302 and traveling upward and outward through the top of the cabinet 302, the principals of the instant invention could be readily applied to an air flow path that entered the top of the cabinet 302 and exited the bottom, or to cabinets with multiple air inlets and outlets, such as a four shelf cabinet with two inlets and two outlets. Finally, it is noted that the radiator trays will increase the pressure drop required to pump air through the cabinet 302, but, they will decrease the required flow rate of air through the cabinet 302, relative to a conventional air-cooled system, due to heat removal from the air before or after each shelf region 304, 306, 308, 310. This could have positive acoustic implications because of the reduced flow rate through the cabinet 302. Acoustic noise is a significant problem for telecommunications service providers.

An alternative embodiment to the system shown in FIG. 3 is shown in FIG. 4. The closed loop system shown here may be useful in reducing the likelihood of harmful airborne contaminants and corrosive gases from interacting with the electrical components of the system. It additionally enables a constant relative humidity and temperature, virtually unaffected by the outside environment. This further increases the robustness and reliability of the overall system of electronics. This design also enables the use of acoustic foam or other sound deadening material to be placed on the cabinet, further reducing acoustic emissions from the air mover used in the closed loop system.

Turning now to FIG. 4, a cabinet 400 is thermally coupled to an external chiller (not shown) via a first heat exchanger 402 located in a return air duct 404 associated with the cabinet 400. A series of smaller heat exchangers 406, 408, 410 are located between shelf regions 412, 414, 416. The smaller heat exchangers are generally responsible for removing the heat generated by components 418, 420, 422 located in each of the shelf regions 412, 414, 416, respectively so as to substantially equalize the temperature of air flowing into each of the shelf regions 412, 414, 416. The heat exchanger 402 is generally responsible for removing any remaining heat and for removing heat pulled out of the air flow by the smaller heat exchangers 406, 408, 410 via a heat exchanger 418 positioned adjacent the heat exchanger 402.

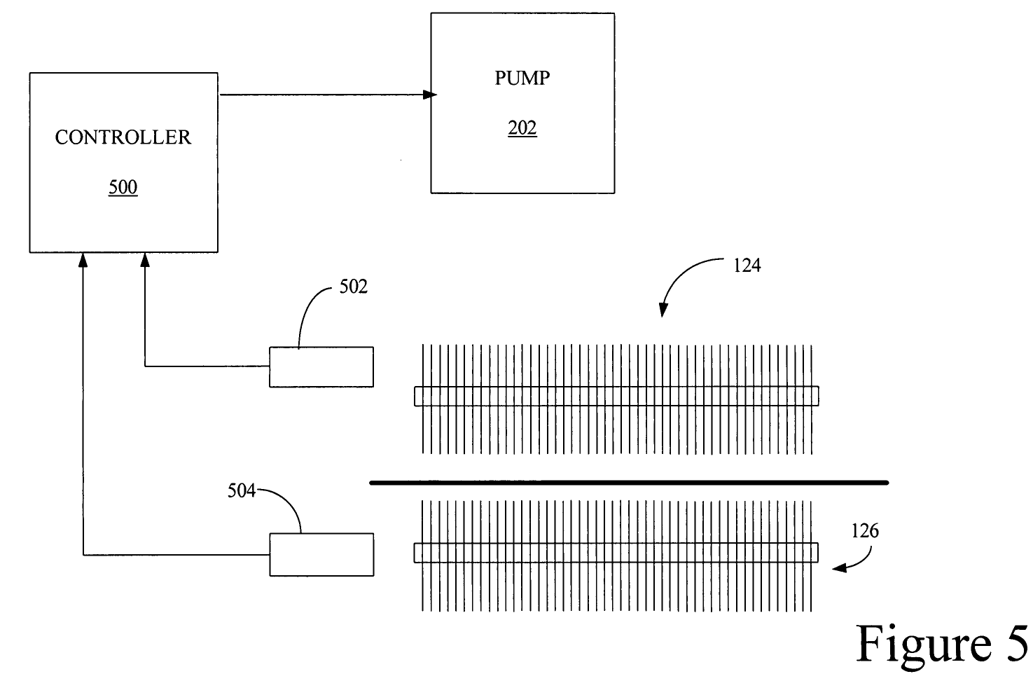

Referring now to FIG. 5, in some embodiments of the instant invention, it may be useful to have the operation of the closed-loop liquid cooling system 200, such as that shown in FIG. 2 to be controlled or otherwise overseen by a controller 500, which may be comprised of various semiconductor devices, which may operate under hard-wired logic control, software control, or a combination thereof. The controller 500 may interface with a variety of sensors 502, 504 located relative to the closed-loop liquid cooling system 200 to provide information to the controller 500 regarding the operation of the closed-loop liquid cooling system 200.

Generally, the controller 500 monitors one or more of the sensors 502, 504 and uses information obtained therefrom to control or alter the operation of the closed-loop liquid cooling system 200. Those skilled in the art will appreciate that the pump 202 may have a variable capacity (such as speed or capacity) that may be altered to change the operating characteristics of the closed-loop liquid cooling system 200. For example, the sensors 502, 504 may take the form of temperature sensors that are positioned to sense the temperature of the cooling air that has passed through heat exchangers 124, 126. The controller 500 may then use the temperature information to alter the operation of the pump 202.

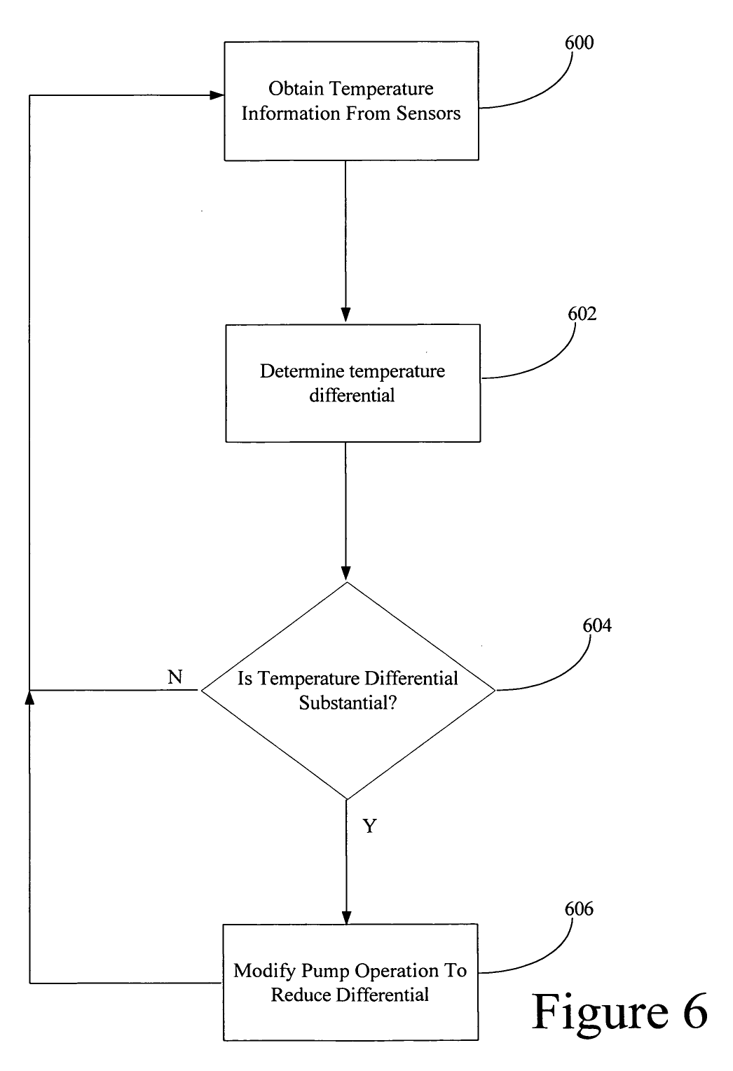

An exemplary embodiment of a software routine that may be employed by the controller 500 is shown in a flowchart representation in FIG. 6. In the illustrated embodiment, the controller 500 utilizes information provided by the sensors 502, 504 to control operation of the pump 202. In particular, the process begins at block 600 with the controller 500 receiving information from the sensors 502, 504. In one exemplary embodiment, the information obtained from the sensors 502, 504 includes information regarding the temperature of the air flows 120, 122.

At block 602, the controller 500 determines the temperature differential, if any, that exists between the air flows 120, 122. At decision block 604, if the temperature differential is insubstantial, then control transfers back to block 600 where the process repeats without any adjustment to the operation of the pump 202 or the closed-loop liquid cooling system 200. On the other hand, if the temperature differential is determined to be substantial, then control transfers to block 606 where the controller takes action to adjust the operation of the pump 202 so as to reduce the determined temperature differential. For example, the speed or capacity of the pump 202 may be increased to increase the ability of the closed-loop liquid cooling system 200 to transfer heat from the higher temperature area to the lower temperature area.

The particular embodiments disclosed above are illustrative only, as the invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
providing a first air flow to a first region in a cabinet;
providing a second air flow to a second region in a cabinet; and
substantially equalizing the temperature of the first and second air flows provided to the first and second regions.

2. A method, as set forth in claim 1, wherein substantially equalizing the temperature of the first and second air flows provided to the first and second regions further comprises transferring heat from the first air flow to the second air flow.

3. A method, as set forth in claim 1, wherein substantially equalizing the temperature of the first and second air flows provided to the first and second regions further comprises transferring heat from one of the first and second air flows having the higher temperature to the other of the first and second air flows having the lower temperature.

4. A method, as set forth in claim 1, wherein substantially equalizing the temperature of the first and second air flows provided to the first and second regions further comprises transferring heat from the first air flow to the second air flow to urge the temperatures of the first and second air flows toward a common temperature.

5. A method, comprising:
providing a first air flow to a first region in a cabinet;
providing a second air flow to a second region in a cabinet; and
transferring heat from the first air flow to the second air flow.

6. A method, as set forth in claim 5, wherein transferring heat from the first air flow to the second air flow further comprises the first and second air flows having a temperature differential therebetween and wherein transferring heat from the first air flow to the second air flow reduces the temperature differential.

7. A method, as set forth in claim 5, wherein transferring heat from the first air flow to the second air flow further comprises the first and second air flows having a temperature differential therebetween and wherein transferring heat from the first air flow to the second air flow substantially eliminates the temperature differential.

8. A method, as set forth in claim 5, wherein transferring heat from the first air flow to the second air flow further comprises substantially equalizing the temperatures of the first and second air flows.

9. A method, as set forth in claim 5, wherein providing the first air flow to the first region in the cabinet further comprises providing the second air flow via an external input directly to the first region.

10. A method, as set forth in claim 9, wherein providing the second air flow to the second region in the cabinet further comprises providing the second air flow via an external input directly to the second region.

11. A method, as set forth in claim 9, wherein providing the second air flow to the second region in the cabinet further comprises providing the second air flow from the first region.

12. An apparatus, comprising:
a cabinet have a first region and a second region and at least one inlet adapted to receive an air flow and pass a first air flow to the first region and a second air flow to the second region; and
a heat exchanger positioned to receive the first and second air flows and transfer heat therebetween.

13. An apparatus, as set forth in claim 12, wherein the heat exchanger further comprises a first heat exchanger positioned to receive the first air flow and a second heat exchanger positioned to receive the second air flow.

14. An apparatus, as set forth in claim 13, wherein the first and second heat exchangers are coupled together in a passive system.

15. An apparatus, as set forth in claim 14, wherein the passive system comprises a heat pipe.

16. An apparatus, as set forth in claim 13, wherein the first and second heat exchangers are coupled together in an active system.

17. An apparatus, as set forth in claim 16, wherein the active system comprises a pump-based fluid circulation system.

18. An apparatus, as set forth in claim 12, wherein said inlet is located adjacent a bottom region of the cabinet.

19. An apparatus, as set forth in claim 12, wherein said inlet is located adjacent a top region of the cabinet.

20. An apparatus, as set forth in claim 12, wherein said inlet comprises first and second inlets located adjacent said first and second regions respectively.
